(19) United States
(12) Patent Application Publication
(10) Pub. No.: US 2011/0044474 A1
(43) Pub. Date: Feb. 24, 2011

(54) System and Method for Adjusting an Audio Signal Volume Level Based on Whom is Speaking

(75) Inventors: Douglas M. Grover, Westminster, CO (US); David S. Mohler, Arvada, CO (US); Christopher P. Ricci, Cherry Hills Village, CO (US)

Correspondence Address: AVAYA INC.;MARGARET CARMICHAEL, DOCKETING SPECIALIST, 1300 W. 120TH AVENUE, ROOM B1-F53, WESTMINSTER, CO, 80234, US

(73) Assignee: AVAYA INC., Basking Ridge, NJ (US)

(21) Appl. No.: 12/543,657

(22) Filed: Aug. 19, 2009

(51) Int. Cl. H03G 3/00; H04M 3/42

(52) U.S. Cl. 381/107; 379/202.01

(57) ABSTRACT

A speech characteristic, such as a volume level of a call participant is derived; the derived speech characteristic is associated with an identifier, such as a caller ID number. The speech characteristic and identifier are stored in a call participant profile. An adjustment of volume level of an audio signal of the call participant is made based on the measured speech characteristic and the identifier in the call participant profile.

In a second embodiment, the system and method can be further adapted to identify a speech characteristic of a participant(s) in a conference call. A determination is made when the participant of the conference call is speaking during the conference call. An adjustment is made to a mixed audio signal of the conference call based on the speech characteristic of the participant in the conference call.

### TECHNICAL FIELD

The system and method relates to adjusting audio signal volume levels and in particular to adjusting audio signal volume levels based on whom is speaking.

### BACKGROUND

During various audio communications, different speakers talk at different volume levels. For example, during one call the speaker may talk softly, causing the listener to turn up the volume. Conversely, on a second call, a different speaker may talk loudly, causing the listener to turn down the volume. This problem can also exist in conference calls where participants in the conference call speak at different levels. Moreover, different speakers speak in different frequency ranges while the listener may hear at a different frequency range. The result is that one speaker may sound louder or softer depending on whom is listening. These problems may require the listener to make periodic adjustments in the volume level based on whom is speaking. These problems can be exacerbated based on the device or quality of the communication channel of the call.

There are some systems that attempt to address the aforementioned issue. There are, for example, systems that adjust the volume level of participants in a conference call prior to mixing the signals of the conference call. In such systems, however, the volume of all speakers in the conference call is adjusted uniformly, without consideration of the individual participant's preferences or hearing abilities. That is, a listener has no control over the relative characteristics of the inputs into the mixed audio signal, only over the volume of the mixed signal itself.

In U.S. Patent Publication No. 2005/0250553, there is described a system in which speaker volume for push-to-talk calls can be adjusted depending on how the user is holding a phone or whether the user is listening on an earpiece. A disadvantage associated with this system is that the volume cannot be adjusted based on who is speaking and/or calling. Again, the listener must adjust the volume up or down based on whom is speaking on the call.

### SUMMARY

The system and method are directed to solving these and other problems and disadvantages of the prior art. A speech characteristic such as a volume level of a call participant is derived; the derived speech characteristic is associated with an identifier such as a caller ID number. The speech characteristic and identifier are stored in a call participant profile. An adjustment of volume level of an audio signal of the call participant is made based on the measured speech characteristic and the identifier in the call participant profile.

In a second embodiment, the system and method can be further adapted to identify a speech characteristic of a participant(s) in a conference call. A determination is made when the participant of the conference call is speaking during the conference call. An adjustment is made to a mixed audio signal of the conference call based on the speech characteristic of the participant in the conference call.

### BRIEF DESCRIPTION OF THE DRAWINGS

These and other features and advantages of the system and method will become more apparent from considering the following description of an illustrative embodiment of the system and method together with the drawing, in which:

FIG. 1 is a block diagram of a first illustrative system for adjusting a volume level.

FIG. 2 is a block diagram of a second illustrative system for adjusting a volume level of a mixed audio signal.

FIG. 3 is an illustrative example of user profile/call participant profiles that are used to adjust a volume level.

FIG. 4 is a flow diagram of a method for adjusting a volume level.

FIG. 5 is a flow diagram of a method for adjusting a volume level of a mixed audio signal.

### DETAILED DESCRIPTION

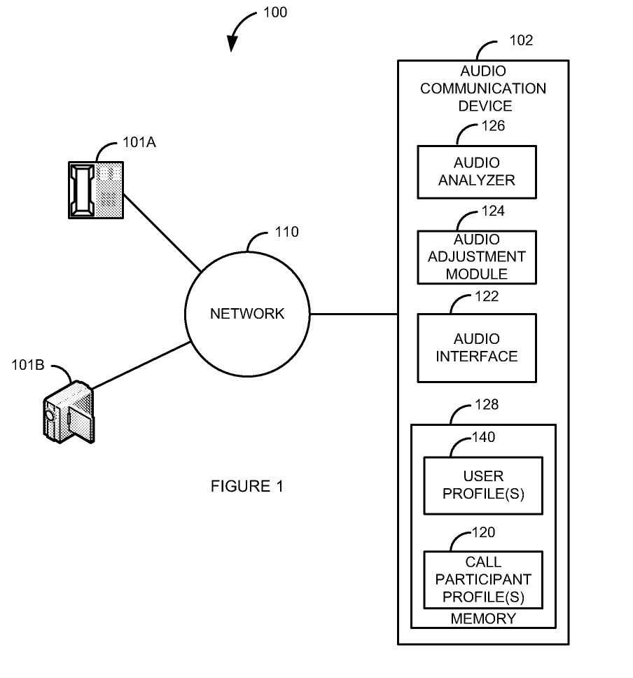

FIG. 1 is a block diagram of a first illustrative system 100 for adjusting a volume level dependent upon whom is speaking. The first illustrative system 100 comprises communication terminals 101, an audio communication device 102, and a network 110. Communication terminals 101 can be any type of device capable of sending and/or receiving an audio signal/stream, such as a telephone, a cellular telephone, a Personal Computer (PC), a video camera, a video monitor, a Personal Digital Assistant (PDA), an auto-dialer in a contact center, a conference bridge, and the like. The audio communication device 102 can be any device capable of receiving an audio signal/stream, such as a desktop telephone, a cellular telephone, a Personal Computer (PC), a video monitor, a Personal Digital Assistant (PDA), a contact center, a conference bridge, and the like. The audio communication device 102 can be a single device and/or can be distributed across multiple devices in the network 110. The network 110 can be any type of network, such as the Internet, a Local Area Network (LAN), a Wide Area Network (WAN), the Public Switched Telephone Network (PSTN), a cellular network, and the like. The network 110 may be various combinations of the above networks.

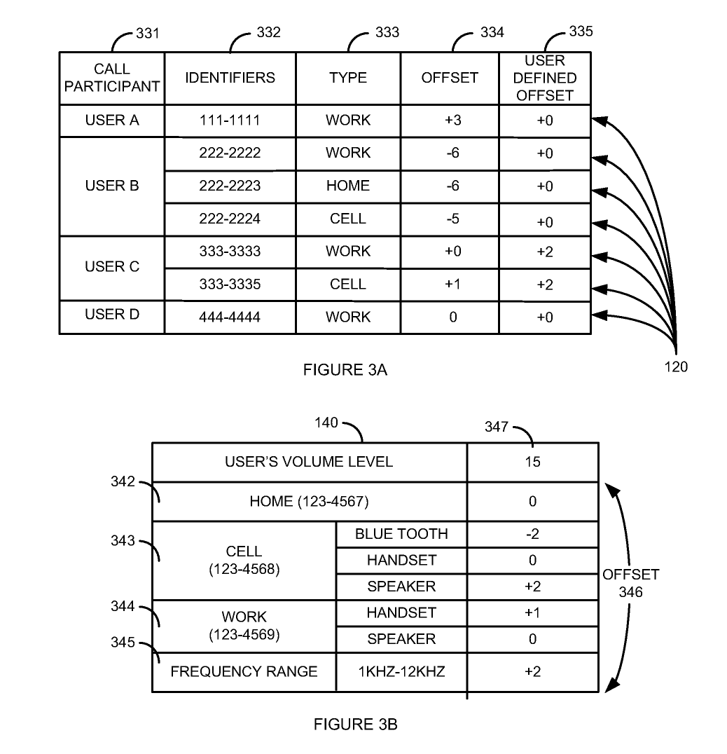

An audio communication device 102 further comprises a call participant profile 120, a user profile 140, an audio interface 122, an audio adjustment module 124, and an audio analyzer 126. The call participant profile 120 and the user profile 140 each reside in a memory 128. The call participant profile 120 (see FIG. 3) is used to store measurements of audio (e.g., speech) characteristics of call(s), offsets, and the like. The call participant profile 120 is shown as being stored in a memory 128 of the audio communication device 102, but could reside in a network device. The user profile 140 (see FIG. 3) is used to store preferences of the user of the audio communication device 102, settings of the audio communication device, and the like. The audio interface 122 is a device or mechanism that generates sounds, such as a loud speaker, a speaker in a hand set/cellular telephone, a speaker in a Bluetooth device, a transducer, and the like. The audio analyzer 126 is a device/software capable of analyzing/processing audio signals such as a commander, a voice recognition module, a frequency analyzer, a digital signal processor, and the like. The audio adjustment module 124 is any device/software capable of processing and adjusting audio signals. The memory 128 is any type of memory that can store information such as Random Access Memory (RAM), programmable memory, flash memory, cache memory in a processor, and the like.

A call is established between a call participant at communication terminal 101 and the audio communication device 102. The call can be any type of call that involves an audio signal such as an analog audio communication, a digital audio communication, a video communication with audio, an audio stream, a video stream with audio, and the like. The call could be live or a recording (e.g., an audio/video stream opened up from a web page). The call can be established from communication terminal 101, the audio communication device 102, a network device, a Private Branch Exchange (PBX), a bridge, a central office switch, a router adapted to establish the call, an auto-dialer in a contact center, and the like.

In the example in FIG. 1, the call is between communication terminal 101A and the audio communication device 102. However, the call can be between two or more audio communication devices 102, or the call can be between various combinations of communication terminals 101 and one or more audio communication devices 102.

The audio adjustment module 124 gets an identifier of the call participant of communication terminal 101A during the call. The identifier could be a caller ID number, a speech pattern of the call participant of communication terminal 101A determined from voice recognition, and the like. The identifier can be any type of communication address such as a telephone number, a Universal Resource Locator (URL), a speech pattern, an avatar, or any unique identifier/number/image to identify the call participant. For example, the audio adjustment module 124 can get a speech pattern from the audio analyzer 126, which created the speech pattern using voice recognition of the call participant from communication terminal 101A. The audio adjustment module 124 can get the identifier using known techniques such as caller ID, and the like.

The audio analyzer 126 derives information of a speech characteristic(s) of the call participant at communication terminal 101A. The derived speech characteristic(s) can be a volume level of the call participant, an offset volume level of the call participant, a volume level of the call participant at a frequency range(s), and the like. The audio analyzer can derive a speech characteristic based on a user changing a volume level on audio communication device 102, user input, and the like. The speech characteristic(s) can be determined during the call, in a prior call with communication terminal 101A, by processes unrelated to a call, and the like. The audio analyzer 126 can measure the audio signal from the call participant at communication terminal 101A to determine an offset to adjust the audio signal. The offset can be a relative or a fixed value. The offset can be relative to a predefined value, an average value, and the like.

The audio adjustment module 124 stores in the memory 128 the derived speech characteristic(s) and the identifier of the call participant of communication terminal 101A in the call participant profile 120. The association of the speech characteristic and the identifier can be accomplished at the time of the call or any time prior to the call.

When the call is established between communication terminal 101A and audio communication device 102, an audio signal from the call participant of communication terminal 101A is received by audio communication device 102. The audio adjustment module 124 initiates an adjustment to a volume level of the received audio signal based on the derived speech characteristic in the user's call participant profile 120, and optionally also on the identity of the user of audio communication device 102. The adjusted audio signal is then used by the audio interface 122 to play the received audio signal. The audio interface 122 can comprise a variety of devices, such as a handset, a headset, a speaker, a transceiver, and a Bluetooth interface.

The adjustment to the volume level of the audio signal can be determined in a variety of ways, such as determining whether or not a speaker's volume exceeds or is below a threshold value for a predetermined duration based on Root Means Square (RMS), and/or peak-to-peak volume measurements based on one or more frequency ranges, and/or in other known ways of determining a signal strength/volume or spectral content. The audio adjustment module 124 can adjust the volume based on samples of the audio signal during a portion of the call, during all of the call, during multiple calls, and the like. The audio adjustment module 124 can adjust the volume based on parameters defined in the user profile 140 (see FIG. 3).

The audio adjustment module 124 can adjust the audio signal volume level based on a derived speech characteristic taken during a previous communication with the call participant at communication terminal 101A. The audio adjustment module 124 can adjust the audio signal volume level by receiving an indication of the audio signal volume level from communication terminal 101A or a device in the network 110. The information on how to adjust the audio signal volume level could be part of the information in a Virtual Business Card (Vcard) that is sent during the call and/or any combination of the above.

The audio adjustment module 124 can adjust the audio signal volume level by comparing the audio signal volume level and the user's volume level 347 (See FIG. 3) setting to produce an offset. For example, if the audio signal's volume level is at a higher level than the user's volume level 347, the audio signal's volume level will be adjusted down. The user's volume level 347 can be an average of the volume level that is set by a user of audio communication device 102, the current set volume level of the communication device 102 a predefined volume level, an average of different volume levels of different communication devices 102 that the user has, and/or other audio volume levels.

The above process can be repeated by deriving a second measurement of the speech characteristic during a second call from a second call participant using a second communication terminal 101. The process gets a second identifier (e.g., a telephone number from the second communication terminal 101). The second speech characteristic and the second identifier are associated with each other and are stored in a second call participant profile 120 (see FIG. 3 for a more detailed example).

The above process can also be repeated for a call from a second call participant on a second communication terminal 101. This would result in the generation of a second profile for the second call participant.

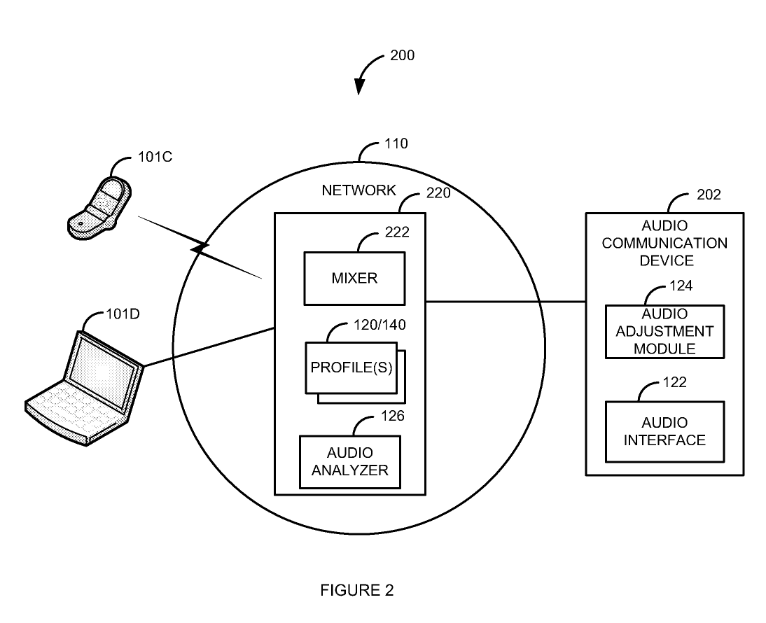

FIG. 2 is a block diagram of a second illustrative system 200 for adjusting a volume level of a mixed audio signal. The second illustrative system 200 comprises communication terminals 101C and 101D, an audio communication device 202, and the network 110. The network 110 comprises network device/bridge 220 that route the communications between the communication terminals 101C, 101D, and audio communication device 202. The network device/bridge 220 can be a variety of devices such as conference bridges, Private Branch Exchanges (PBX), central office switches, routers, gateways, and the like. In this example, the network device/bridge 220 comprises a mixer 222, the call participant profile(s) 120/user profile(s) 140, and the audio analyzer 126. The mixer 222 is used to mix audio signals of a conference call of three or more parties on the conference call. The audio communication device 202 comprises the audio adjustment module 124 and the audio interface 122.

In this illustrative example, the call participant profile 120, the user profile 140, the audio analyzer 126, and the audio adjustment module 124 are shown as being distributed between the network device/bridge 220 and the audio communication device 202. However, the call participant profile 120, the user profile 140, the audio analyzer 126, and the audio adjustment module 124 can all be in the network device/bridge 220, the audio communication device 202, and/or any combination of the network device/bridge 220 and the audio communication device 202.

A conference call (e.g., a video or audio conference call) is established between communication terminal 101C, communication terminal 101D, and the audio communication device 202. The conference call is established through mixer 222 (e.g., a mixer 222 in an audio bridge or video bridge 220). As the conference call is established, the mixer 222 determines the communication device's (101C and 101D) identification numbers using, for example, caller ID.

When the conference call is established, the audio signals from each of the call participants of communication devices 101C and 101D are mixed by the mixer 222. The audio analyzer 126 determines when a call participant (calling from communication terminal 101C and/or 101D) is speaking. The audio analyzer 126 determines when the call participant is speaking based on voice recognition, from an identifier, and/or the like. The audio analyzer 126 derives a speech characteristic of a participant (e.g., how loudly/softly the call participant is speaking) in the conference call while the call participant is speaking during the conference call in the mixed audio stream. The audio adjustment module 124 initiates an adjustment to the mixed audio signal based on the speech characteristic and when the call participant is speaking.

Consider the following example to illustrate how this works. A conference call is established between communication terminals 101C, 101D, and audio communication device 202. The audio signals from communication terminals 101C and 101D are mixed by the mixer 222. The call participant using communication terminal 101C speaks. The audio analyzer 126 determines from the mixed audio signal when the call participant using communication terminal 101C is speaking using voice recognition software/hardware. The audio analyzer 126 also measures how loudly or softly (speech characteristic) the call participant using communication terminal 101C is speaking to produce a relative offset (e.g., relative to the volume level of the communication device 202). The communication terminal's 101C identification number (identifier), the offset, and a sample of a speech pattern (identifier) of the call participant using communication terminal 101C are stored and associated in the call participant profile 120 for use on additional conference calls and/or the current conference call.

The audio adjustment module 124 initiates the adjustment of the mixed audio signal using the offset (which is sent from the network device/bridge 220) when the call participant using communication terminal 101C is speaking. This could be done by sending a marker in the mixed audio stream indicating the offset and when to adjust the mixed audio signal using the offset. The offset could be used in conjunction with a user defined offset and/or an offset for a particular audio interface 122 such as a speaker phone or Bluetooth device. In another exemplary embodiment, the audio adjustment module 124 could be in the network device/bridge 220 and adjust the mixed audio signal before sending the mixed audio signal to the audio communication device 202. In yet another exemplary embodiment, the call participant profile 120, the user profile 140, the network analyzer 126 and the audio adjustment module 124 can all be an audio communication device 202.

Another example is a call is made from a communication terminal 101 to a communication device 102; the communication terminal 101 is a device capable of conferencing multiple call participants. The audio adjustment module 124 can initiate an adjustment of the audio signal from the conferenced participants using voice recognition of individual call participants. The audio adjustment module 124 can then adjust the conferenced audio signal up or down based on who is speaking on the conferenced audio signal.

FIG. 3A is an illustrative example of call participant profiles 120 that are used to adjust a volume level. The call participant profiles 120 described in FIG. 3 are illustrative examples of one of many different types of call participant profiles 120 that can be used. A call participant profile 120 contains a name, or other identifier, of a call participant 331, an identifier 332 of communication terminals used by each identified call participant, a type 333 of the identified communication terminal, a level offset 334 for that communication terminal 101 and user combination, a user defined level offset 335, and the like. Each row in FIG. 3A represents a profile 120 of a call participant. One skilled in the art will recognize that the profiles 120, 140 can be created in real time at the inception of a new call, placed in a permanent database, or a combination of the two, such as a permanent database of profiles associated with members of a contact list and a temporary database of profiles associated with unidentified lines.

The name, or other identifier, of the call participant 331 and the identifier 332 can be passed to the audio communication device 102/202 at any time during and/or prior to the communication (e.g., using known caller ID parameters sent during ringing). The type 333 can be user-defined or sent to the audio communication device 102/202 during the communication and/or prior to the communication. The communication terminal level offset 334 is a relative volume level (e.g., decibels). The offset 334 can be determined by comparing the audio signal volume level to a user's volume level 347. In this example, the offset 334 is a delta between the call participant's audio signal volume level and the user of the user's volume level 347 (e.g., a current volume level, average volume level or defined volume level). In FIG. 3A, the offset 334 can be positive or negative; the offset 334 is the amount of volume that is added to the received audio signal. If the offset 334 is negative, the offset is the amount of volume that is subtracted from the received audio signal. The user of the audio communication device 102/202 can also define a user-defined offset 335. The user-defined offset 335 is an additional volume level that is either added or subtracted based on whom the call participant is. The offset 334 is shown in absolute offsets (db), but one skilled in the art will recognize that they can also be offsets or multipliers relative to a particular user or device.

FIG. 3B is an illustrative example of a user profile 120 that is used to adjust a volume level. The user profile 140 contains a user's volume level 347. The user profile 140 can also have offsets 346 that are based on other audio communication devices 102/202 (342-344) associated with the owner of the user profile 140. Each audio communication device 102/202 (represented by 342-344) may have different defined audio interfaces 122. For example, cell phone 343 has defined audio interfaces 122 for a Bluetooth interface, a handset interface, and a speaker interface. Also, there can be defined frequency range(s) 345 that can be defined for use by the audio adjustment module 124 to add or decrease the received audio signal in one or more of these frequency ranges. The defined frequency range(s) can be defined by the user profile 140, by samples made by the audio analyzer 126, and the like.

As an example, assume that USER A is in his/her office and places a telephone call to the owner of the user profile 140 at his/her home phone. From measurements of audio signals gathered during one or more previous calls placed by USER A from the same telephone number 332 to the home of the owner of the user profile 140, it has been determined that USER A is relatively soft-spoken and an offset of +3 is determined to compensate for USER A's low speech volume. The next time USER A calls from work, the system increases the volume using the offset of +3 in relation to the user's volume level 347. In addition, the user profile 140 has defined an offset 346 of 0 for calls to home, which in this case does not change the volume level. The offset 346 for the home audio communication device 342 can be user defined, defined using a default value, and the like.

In another example, USER B has an exceptionally deep and/or loud voice. The system has determined, based on prior measurements of an audio signal(s) from USER B's communication terminals 101, an offset range of from −5 to −6. If a call is placed from USER B's home telephone to the cell phone 343 of the owner of the user profile 140 using the Bluetooth audio interface 122, the system will decrease the volume level of the call by a −8 offset (−6 USER B's home phone offset and −2 for cell phone 343 using Bluetooth offset) in relation to the user's volume level 347.

In a third example, USER C uses his cell to place a call to the owner of the user profile 140. Since USER C has an East coast accent, the user profile 140 has assigned a +2 offset to make sure he can understand what USER C is saying. In addition, the user profile 140 has defined a +2 in the 1 Kilohertz to 12 Kilohertz frequency range because he is hard of hearing. When a call from USER C is answered by the owner of the user profile 140 using his/her speakerphone at work, the offset used for the call is +1 (USER C's cell), +2 (the profile user defined offset 335 for USER C), 0 (the profile user's work phone speaker offset), and +2 for the 1 KHz to 12 KHz frequency range. The total would be +5 for 1 KHz to 12 KHz range and +3 for frequency ranges outside 1 KHz to 12 KHz for the call with USER C. The offsets are added in relation to the user volume level 347.

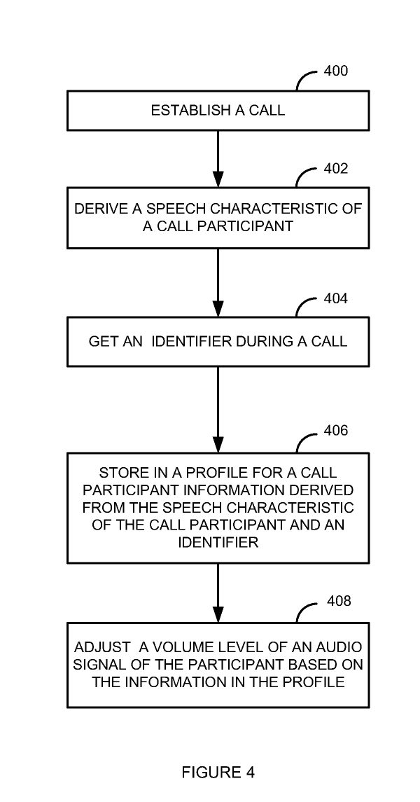

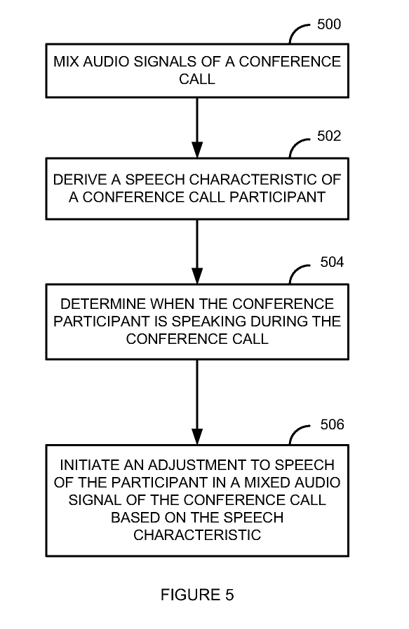

FIG. 4 is a flow diagram of a method for adjusting a volume level. Illustratively, the communication terminals 101, the audio communication device 102, the audio analyzer 126, and the audio adjustment module 124 are stored-program-controlled entities, such as in a computer, which performs the method of FIGS. 4-5 by executing a program stored in a storage medium, such as a memory or disk.

The process begins when a call is established 400 between a call participant at the communication terminal 101 and a call participant at the audio communication device 102 with the call participant profile 120 and the user profile 140. The call can be initiated by or to the call participant having the user profile 140. The audio analyzer 126 derives 402 information from a speech characteristic (e.g., measuring a volume level of the call participant) of the call participant at the communication terminal 101. The audio adjustment module 124 gets or assigns 404 the identifier during the call. The identifier can be a call participant speech pattern used/created by the audio analyzer 126 to identify the call participant; the call participant identifier can be a caller ID number, a telephone number, and the like.

The audio adjustment module 124, stores 406 and associates information derived from the measurement of the speech characteristic and the identifier of the call participant in the call participant profile 120. The audio adjustment module 124 initiates 408 an adjustment to a volume level of an audio signal received during the call from the call participant. The adjustment can be based on a determined offset that is the difference between the volume level of the audio signal and a user's volume level 347.

FIG. 5 is a flow diagram of a method for adjusting a volume level of a mixed audio signal. The mixer 222 mixes 600 audio signals of a conference call. The mixed audio signal is a mixture of at least two audio signals from conference call participants. The audio analyzer 126 derives 502 information from a speech characteristic(s) of a conference call participant(s). The audio analyzer 126 determines 504 when the conference call participant(s) is speaking during the conference call. The audio adjustment module 124 initiates 506 an adjustment to the speech of the call participant in the mixed audio signal of the conference call based on the measured speech characteristic.

One variation that comes to mind is another offset that deals with environmental noise. For example, if an individual, “Chris,” is traveling in an airport and wants to select another offset (positive) to deal with the fact that the ambient noise is high, he can manually select it. Alternatively, if his device has the ability to measure or cancel the ambient noise, he can utilize these device features in association with the profiles. Another variation that comes to mind is the ability to have the system detect where a user changes phones during a communication session and the system automatically detects the change in routing and beneficially selects the appropriate profile for the new device. Yet another variation would be the ability to apply this idea to Avatars where the sender has defined a voice, level, etc., for the Avatar and the user wishes to adjust them. Still another variation would be the video equivalent of this idea where the luminance and chrominance of the video signal can be preferentially adjusted to deal with differences in cameras or displays.

The phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising”, “including”, and “having” can be used interchangeably.

Of course, various changes and modifications to the illustrative embodiment described above will be apparent to those skilled in the art. These changes and modifications can be made without departing from the spirit and the scope of the system and method and without diminishing its attendant advantages. The above description and associated Figures teach the best mode of the invention. The following claims specify the scope of the invention. Note that some aspects of the best mode may not fall within the scope of the invention as specified by the claims. Those skilled in the art will appreciate that the features described above can be combined in various ways to form multiple variations of the invention. As a result, the invention is not limited to the specific embodiments described above, but only by the following claims and their equivalents.

What is claimed is:

1. A method for adjusting a volume level of one or more call participants in response to differences in speech characteristics of the one or more call participants, comprising:
a. deriving information from at least one speech characteristic of the one or more call participants;
b. storing the information in a call participant profile of the one or more call participants; and
c. adjusting the volume level of the one or more call participants during a call based on the information in the call participant profile.

2. The method of claim 1, wherein the derived information is an offset.

3. The method of claim 1, further comprising getting an identifier of one of the call participants.

4. The method of claim 3, wherein the identifier is a caller ID number or a call participant speech pattern, and wherein one of the at least one speech characteristics is a volume level of the one call participant, wherein the deriving step comprises:
determining an offset comprising a difference between the volume level of the one call participant and a volume level of an audio communication device, and wherein step (c) further comprises adjusting the volume level of the one call participant based on the offset.

5. The method of claim 3, further comprising getting a frequency range offset, and further adjusting the volume level of the one or more call participants based on the frequency range offset.

6. The method of claim 3, further comprising getting a user defined offset, and further adjusting the volume level of the one or more call participants based on the user defined offset.

7. The method of claim 3, wherein the identifier is a call participant speech pattern, and wherein the one call participant is identified with the call participant speech pattern based on voice recognition.

8. The method of claim 3, wherein the identifier is a first caller ID number, the method further comprising:
deriving information from at least one speech characteristic of the one call participant on a second call; and getting a second caller ID number of the one call participant; and going to step (c).

9. The method of claim 1, wherein the call participant profile is stored in an audio communication device or in a network device.

10. The method of claim 1, wherein the call is initiated by one or more items selected from the group comprising: an audio communication device, a communication terminal, a network device, a Private Branch Exchange (PBX), a bridge, a central office switch, a router adapted to establish the call, and an auto-dialer in a contact center.

11. The method of claim 1, further comprising getting an offset for an audio interface and further adjusting the volume level of the one or more call participants during the call based on the offset and wherein the audio interface is an item selected from the group comprising: a handset, a headset, a speaker, and a Bluetooth interface.

12. The method of claim 1, wherein:
storing the information in the call participant profile comprises storing a plurality of call participant profiles for each call participant each corresponding to a different one of a plurality of identifiers and containing the derived information of at the least one speech characteristic of the call participant with respect to said identifier; and
adjusting the volume level comprises in response to a call participated in by one of the call participants, determining at least one of the plurality of identifiers that corresponds to the call, in response to the determining, adjusting a volume level of an audio signal of the call participant based on the information in the call participant profile corresponding to the at least one identifier.

13. The method of claim 12, wherein each identifier comprises a different identifier of the call participant.

14. The method of claim 1, wherein the call participant profile is a call participant profile of one of the call participants and the one of the call participants is a first call participant, further comprising:
storing a second call participant profile for a second call participant containing information concerning at least one audio characteristic of audio received by the second call participant; and
in response to a call participated in by the second call participant, adjusting a volume level of an audio signal of the second call participant based on information in the second call participant profile.

15. A method for adjusting a volume level of one or more call participants in a conference call comprising:
a. deriving information from at least one speech characteristic of at least one of the conference call participants;
b. determining when the at least one of the conference call participant is speaking during the conference call; and
c. adjusting speech of the at least one conference call participant in a mixed audio signal of the conference call based on the derived information.

16. The method of claim 15, further comprising a mixer adapted to mix audio signals of the conference call.

17. A system for adjusting a volume level of one or more call participants in response to differences in speech characteristics of one or more of the call participants, comprising:
a. an audio analyzer that derives information from at least one speech characteristic of one or more of the call participants;
b. a memory device adapted to store a call participant profile of one or more of the call participants; and
c. an audio adjustment module that adjusts the volume level of one or more of the call participant based on the information in the call participant profile.

18. The system of claim 17, wherein the derived information is an offset.

19. The system of claim 17, further comprising getting an identifier of one of the call participants.

20. The system of claim 19, wherein the identifier is a caller ID number or a call participant speech pattern, and wherein one of the at least one speech characteristics is a volume level of the one call participant, and wherein the audio adjustment module is further adapted to determine an offset, comprising a difference between the volume level of the one call participant and volume level of an audio communication device, and adjust the volume level of the one call participant based on the offset.

21. The system of claim 19, wherein the audio adjustment module is further adapted to get a frequency range offset and further adjust the volume level of the one or more call participants based on the frequency range offset.

22. The system of claim 19, wherein the audio adjustment module is further adapted to get a user defined offset, and further adjusting the volume level of the one or more call participants based on the user defined offset.

23. The system of claim 19, wherein the identifier is a call participant speech pattern, and wherein the audio analyzer is further adapted to identify the one call participant with the call participant speech pattern based on voice recognition.

24. The system of claim 19, wherein the identifier is a first caller ID number, and wherein the audio adjustment module is further adapted to derive information from at least one speech characteristic of the one call participant on a second call and get a second caller ID number of the one call participant.

25. The system of claim 17, wherein the call participant profile is stored in an audio communication device or in a network device.

26. The system of claim 17, wherein the call is initiated by one or more items selected from the group comprising: the an audio communication device, a communication terminal, a network device, a Private Branch Exchange (PBX), a bridge, a central office switch, a router adapted to establish the call, and an auto-dialer in a contact center.

27. The system of claim 17, wherein the audio adjustment module is further adapted to get an offset for an audio interface and further adjusting the volume level of the one or more call participants during the call based on the offset wherein the audio interface is an item selected from the group comprising: a handset, a headset, a speaker, and a Bluetooth interface.

28. The system of claim 17, wherein the audio adjustment module is further configured to store a plurality of call participant profiles for each call participant, each corresponding to a different one of a plurality of identifiers and containing the derived information of the at least one speech characteristic of the call participant with respect to said identifier, and in response to a call participated in by the call participant, determine at least one of the plurality of identifiers that corresponds to the call, responsive to the determining, adjusting a volume level of an audio signal of the call participant based on the information in the call participant profile corresponding to the at least one identifier.

29. The system of claim 28, wherein each identifier comprises a different identifier of the call participant.

30. The system of claim 17, wherein the call participant profile is a call profile of one of the call participants and the one of the call participants is a first call participant, wherein the audio adjustment module is further configured to store a second call participant profile for a second call participant containing information concerning at least one audio characteristic of audio received by the second call participant, and in response to a call participated in by the second call participant, adjusting a volume level of an audio signal of the second call participant based on information in the second call participant profile.

31. A system for adjusting a volume level of one or more call participants in a conference call comprising:
a. an audio analyzer adapted to derive information from at least one speech characteristic of at least one of the conference call participants and determine when the at least one of the conference call participants is speaking during the conference call; and
b. an audio adjustment module adapted to adjust speech of the at least one conference call participant in a mixed audio signal of the conference call based on the derived information.

32. The system of claim 31, further comprising a mixer adapted to mix audio signals of the conference call.
